(19) United States
(12) Patent Application Publication
(10) Pub. No.: US 2006/0033047 A1
(43) Pub. Date: Feb. 16, 2006

(54) Method of controlling crystal surface morphology using metal adsorption

(75) Inventors: Se-ahn Song, Seoul (KR); Alexander V. Latyshev, Novosibirsk (RU); Sergey S. Kosolobov, Novosibirsk (RU); Anton K. Gutakovskii, Novosibirsk (RU); Ludmila I. Fedina, Novosibirsk (RU)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-do (KR)

(21) Appl. No.: 11/185,728

(22) Filed: Jul. 21, 2005

(30) Foreign Application Priority Data
Aug. 12, 2004 (KR) 2004-0063509

(51) Int. Cl. H01J 37/08

(52) U.S. Cl. 250/492.21

(57) ABSTRACT

Embodiments include a method of forming a crystal surface with uniform monoatomic steps using metal adsorption. The method of controlling crystal surface morphology may include heating crystal to a predetermined temperature by applying a direct current (DC) voltage to its both ends; and depositing metal atoms to the crystal surface heated to a predetermined temperature at a predetermined depositing rate while maintaining the application of DC voltage so as to form monoatomic steps on the crystal surface.

### BACKGROUND OF THE DISCLOSURE

This application claims the benefit of Korean Patent Application No. 10-2004-0063509, filed on Aug. 12, 2004, in the Korean Intellectual Property Office, the disclosure of which is incorporated herein in its entirety by reference.

1. Field of the Disclosure

Embodiments of the present invention relates to a method of controlling crystal surface morphology using metal adsorption, and more particularly, to a method of forming a crystal surface having uniform monoatomic steps using metal adsorption.

2. Description of the Related Art

As the importance of nanotechnology is gradually increased, considerable amounts of research on surface reactions and a structure of a crystal at an atomic level are being conducted. In particular, a technology to both form and control a well-defined and stable crystal surface morphology at an atomic level is being investigated. However, there is no attempt to control the crystal surface morphology so as to form the surface of the crystal, such as Si or Ge, GaAs, having a specific form of an atomic step structure. A technology to control the crystal surface of the atomic step structure is expected to be very useful in the fabrication of nano-sized objects.

One of the conventional technologies that meticulously control the crystal surface morphology is disclosed in U.S. Pat. No. 6,743,495, issued to Jiri L. Vasat et al., entitled “Thermal Annealing Process for Producing Silicon Wafers with Improved Surface Characteristics”, filed on Jun. 1, 2004. The above patent is mainly directed to eliminating defects generated on the silicon crystal surface. According to the above patent, the silicon wafer surface is cleaned by exposing it to H₂, HF or HCI atmosphere at about 1100° C., and then the cleaned silicon wafer surface is exposed to an atmosphere including a monoatomic noble gas or vacuum at about 1100° C. to eliminate the defects from the silicon wafer surface. According to this method, a clean silicon wafer surface at an atomic level is obtained, but it is impossible to control the atomic step to a desired form.

A method of controlling the silicon crystal surface to a desired form of an atomic step is disclosed by A. V. Latyshev, et al., [“Transformations on Clean Si(III) Stepped Surface during Sublimation”, Surface Science Vol. 213, pp. 157-169, Apr. 2, 1989]. According to this method, when the silicon crystal is annealed at 1260° C. by directly applying an AC or DC voltage to it under ultravacuum (about 10⁻¹⁰ torr), the migration of atoms of the silicon crystal surface is induced to obtain a relatively uniform atomic step. This method uses electromigration that atoms migrate when the movement of electrons actively occurs and the temperature is very high while the current and voltage in a semiconductor are held constant.

FIG. 1 illustrates silicon surface morphology obtained by applying a DC voltage to a Si (111) surface and annealing it at 1260° C. according to the above method. As illustrated in FIG. 1, when the silicon surface is heated to a high temperature using a DC voltage, relatively uniform atomic steps can be obtained.

In this method, the atomic steps of the silicon crystal surface generally initiates a parallel migration in a direction of a step-up at about 1000° C., but the migration direction and width of the atomic steps cannot be controlled accurately. Also, Si sublimation is inhibited at 1000° C. or less so that the silicon crystal surface morphology is stably maintained. Thus, it is impossible to form the atomic steps in a desired form. However, when performing the heat treatment at 1200° C. or more, it is very difficult to obtain uniform atomic steps due to evaporation or sublimation of silicon on its surface. Considerably long reaction times, such as several hours, are required to obtain relatively uniform atomic steps.

### SUMMARY OF THE DISCLOSURE

Embodiments of the present invention may provide a method of controlling the morphology of a surface of a crystal, such as silicon and the like, having a clean surface at an atomic level under ultravacuum.

The present invention may also provide a method of controlling the morphology of a surface of a crystal, such as silicon and the like, so as to have uniform atomic steps even at relatively low temperatures and short reaction times.

According to an aspect of the present invention, there is provided a method of controlling a crystal surface morphology, the method including: heating a crystal to a predetermined temperature by applying a direct current (DC) voltage to its both ends; and depositing metal atoms at a predetermined deposition rate on the crystal surface, which has been heated to a predetermined temperature, while maintaining the application of the DC voltage so as to form monoatomic steps on the crystal surface.

The heating temperature of the crystal may be in a range of about 700 to about 1000° C. and the depositing rate of the metal atoms may be in a range of about 0.001 to about 1,000 ML/min. In this case, the depositing of the metal atoms may be performed in a vacuum state of about 10⁻⁹ to about 10⁻¹¹ torr. The metal atom may be at least one selected from the group consisting of Au, Ti, Ni, Co, Cu, V, Re, Mo, and Pt. Also, the crystal is a monocrystal of a semiconductor.

The method of controlling crystal surface morphology according to an embodiment of the present invention further includes removing the metal atoms deposited on the crystal surface after forming the monoatomic step in the crystal surface.

### BRIEF DESCRIPTION OF THE DRAWINGS

The above and other features and advantages of the exemplary embodiments will become more apparent by describing in detail exemplary embodiments with reference to the attached drawings in which:

FIG. 1 illustrates silicon surface morphology obtained by applying a DC voltage to a Si (111) surface and annealing it at 1260° C. according to a conventional method;

FIG. 2 is a schematic diagram of an apparatus for controlling a crystal surface morphology according to an embodiment of the present invention;

FIG. 3 illustrates a principle of a method of controlling a crystal surface morphology according to an embodiment of the present invention;

FIGS. 4A through 4D sequentially illustrate changes in the crystal surface morphology according to the first Example of the present invention; and

FIG. 5 is a graph illustrating the relationship between an average width of the atomic steps and time in the method of controlling the crystal surface morphology according to the present invention.

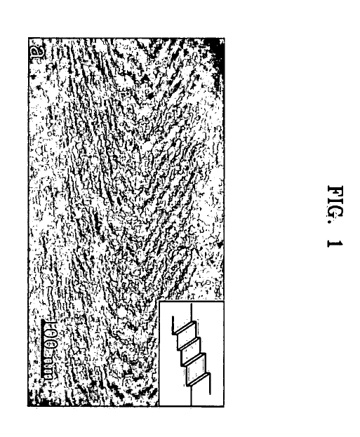

### DETAILED DESCRIPTION OF EXEMPLARY EMBODIMENT OF THE DISCLOSURE

Hereinafter, a method of controlling the crystal surface morphology according to an embodiment of the present invention will be described in more detail with reference to the attached drawings.

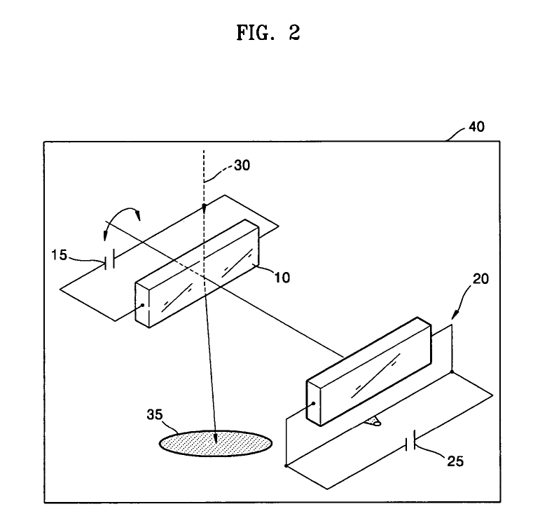

FIG. 2 schematically illustrates an apparatus for controlling the crystal surface morphology according to the present invention. As illustrated in FIG. 2, the control of the crystal surface morphology according to an embodiment of the present invention may be achieved, for example, in an ultravacuum chamber 40 of an ultra high vacuum reflection electron microscope (UHV-REM). In the ultravacuum chamber 40, a sample crystal substrate 10 and a DC power source 15 for applying a voltage to the sample crystal substrate 10 may be installed. A metal depositing device 20 for depositing metal atoms on the sample crystal substrate 10 and a heater power source 25 for applying a voltage to the metal depositing device 20 may also be installed. Although it is not shown in FIG. 2, a hot plate for heating the sample crystal substrate 10 may be further included. Also, a fluorescent plate 35 for observing and analyzing images and diffraction patterns formed by an electron beam reflected on the surface of the sample crystal substrate 10 may further be installed. Thus, it is possible to observe, in real time, minute changes in the surface morphology of the sample crystal substrate 10 through the fluorescent plate 35. The observation of a fine surface through the UHV-REM is known in the art, and thus, more specific description thereof will be omitted herein.

In the ultravacuum chamber 40 having the structure as described above, the method of controlling the crystal surface morphology according to an embodiment of the present invention is as follows. First, the internal space of the ultravacuum chamber 40 may maintained in a vacuum state of about 10⁻¹⁰ torr and the sample crystal substrate 10 may be heated to about 700 to about 1000° C. by applying DC voltage to it. In this case, the sample crystal substrate 10 may be heated with the hot plate as described above. Then, metal atoms may be deposited on the surface of the sample crystal substrate 10 through the metal depositing device 20. The deposition rate of the metal atoms may be properly controlled considering the uniformity of monoatomic steps, etc., and may be in a range of about 0.001 to about 1.000 ML/min. Examples of the metal that can be deposited on the surface of the sample crystal substrate 10 includes Au, Ti, Ni, Co, Cu, V, Re, Mo and Pt. In particular, Au may be used on the surface. The magnitude of the DC voltage applied to both ends of the sample crystal substrate 10 may be varied depending on the type of crystal sample and is commonly in a specific range to heat the crystal sample surface to about 700° C. or more. Specifically, in the case of a silicon monocrystal, the magnitude of DC voltage may be in a range of about 10 to about 100 V.

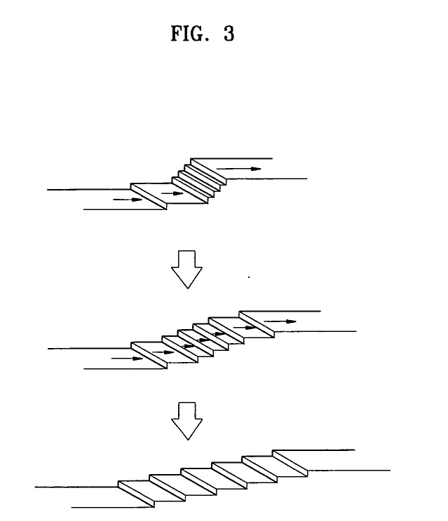

As described in the description of the related art, since the surface morphology is stably maintained due to the inhibition of the sublimation in the crystal surface at 1000° C. or less, the atomic steps in a desired form is not formed. However, when depositing metal atoms as in the present invention, the crystal surface becomes thermodynamically unstable. Thus, when depositing the metal atoms while applying the DC voltage to the sample crystal substrate 10, the atoms of the crystal surface may start to migrate in a certain direction according to the electromigration phenomenon as described above. As a result, non-uniform steps of the crystal surface may continue to migrate in a certain direction and, after a period, very uniform monoatomic steps may be formed on the crystal surface, as exemplarily illustrated in FIG. 3. In the present invention, since the migration of atoms may be promoted by the metal atoms deposited on the surface of the sample crystal substrate 10, uniform and even monoatomic steps can be obtained within about 1 to about 1000 seconds according to the type of the sample crystal, the heating temperature, and the rate of depositing the metal atoms.

Meanwhile, if the application direction of DC voltage is inversed, the current may flow inversely, and thus, the migration of the steps may also be inversed. In this case, if the steps are formed in the same direction as illustrated in FIG. 3, uniform monoatomic may be steps are transformed into non-uniform step bunches. Meanwhile, if steps are formed in an inverse direction to the direction of FIG. 3, the non-uniform atomic steps are transformed into uniform monoatomic steps. Thus, by controlling the direction of the DC voltage to both ends of the crystal, it is possible to accurately control the formation direction and state of atomic step, and the like.

As described above, this electromigration phenomenon is conventionally occurred at very high temperatures, for example, at about 1200° C. However, in the present invention, the electromigration phenomenon may occur even at a low temperatures, for example, at about 1000° C. or less by depositing metal atoms on the crystal surface. Thus, in the present invention, since sublimation or evaporation in the crystal surface due to high temperatures does not occur, it is possible to form finer monoatomic steps. Furthermore, in the present invention, since the atomic steps are allowed to migrate continuously in the same direction using only a DC voltage, it is possible to arbitrarily control the width of the atomic steps.

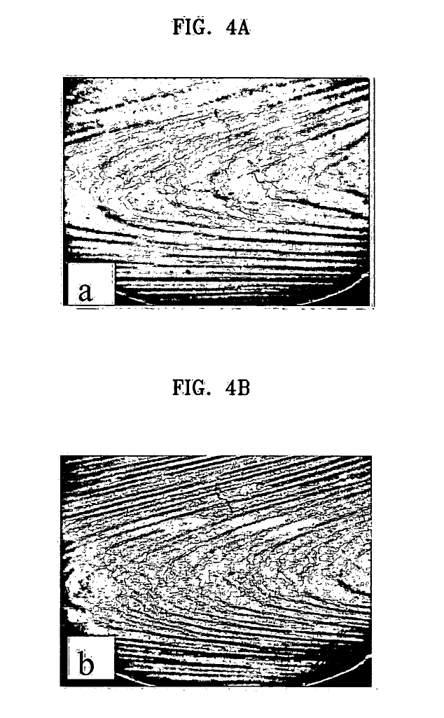

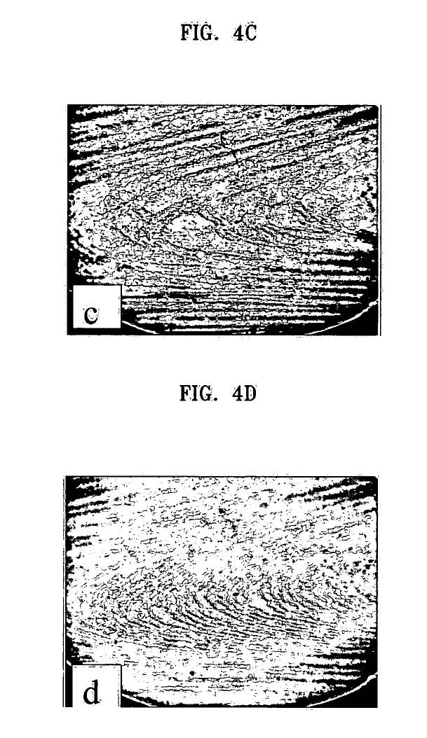

FIGS. 4A through 4D sequentially illustrate the changes in the crystal surface morphology according to the first Example of the present invention. The first Example was performed observing in real time the changes of a sample surface by irradiating an electron beam onto the surface of the sample in the ultravacuum chamber 40 of UHV-REM as described above. The sample used was prepared by slicing a standard wafer of a (111) silicon monocrystal surface with a miscut angle corresponding to a width of a step of about 100 nm to the size of 8 mm×1 mm×0.3 mm. Here, the cutting direction was set for the atomic steps to be perpendicularly formed to a longer side of the sample. A sample holder was particularly fabricated so as to supply a DC to the sample. Meanwhile, although a (111) silicon monocrystal surface was used in this Example, a crystal having a surface of low refractive index, such as a (100) surface or (110) surface, may also be used.

In this state, the silicon sample was annealed in the ultravacuum chamber 40 of the electron microscope at 1260° C. for several minutes to clear the surface. Au was deposited on the sample surface at a rate of 0.018 ML/min while heating the cleared sample at an atomic level to about 860° C. by applying a DC voltage to it. As a result, the silicon crystal surface is sequentially changed from FIG. 4A to FIG. 4D. Referring to FIGS. 4A through 4D, an atomic step of the sample surface gradually became uniform. As seen from FIG. 4D illustrating the surface state about 50 seconds after the beginning of the deposition of Au, ununiform monoatomic steps as in FIGS. 4A through 4C were transformed into very uniform monoatomic steps. In a conventional method, a maximum of several hours was required to form relatively uniform monoatomic steps. However, in the present invention, more uniform monoatomic steps could be formed in only about 50 seconds.

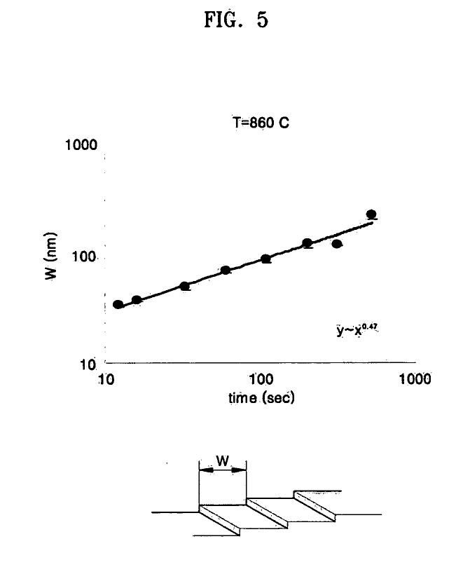

Meanwhile, FIG. 5 is a graph illustrating the changes in an average width of the monoatomic steps with respect to time in the method of controlling the crystal surface morphology according to the present invention. When depositing Au on (111) silicon monocrystal surface at 0.018 ML/min while heating it at about 860° C. as in the first Example, the average width (W) of the monoatomic steps increases with time, indicating that the crystal surface eventually becomes more uniform. Referring to FIG. 5, when time is represented by x axis and the average width of the monoatomic steps is represented by y axis, the relationship is approximately y˜x^{0.47}. Thus, by controlling the time of depositing metal atoms, it is possible to arbitrarily control the average width of the monoatomic steps.

After arbitrarily controlling the crystal surface morphology as described above, the metal atoms deposited on the crystal surface may be removed, if necessary, for example, through etching and the like.

Although a silicon monocrystal was used in the above Example, the method of controlling the crystal surface morphology according to the present invention is not limited only to silicon. It is also possible to control a monocrystal surface of, for example, a semiconductor, such as Ge or GaAs, and other kinds of monocrystals in addition to silicon.

The method of controlling the crystal surface morphology according to the present invention has been described in detail. As described above, according to the present invention, it is possible to control the crystal surface morphology at an atomic level. In particular, it is possible to control crystal surface so as to have uniform atomic steps, even at relatively low temperatures and short reaction times. Thus, manufacturing time and costs can be reduced.

Moreover, by forming crystal surface with uniform atomic steps according to the present invention, a crystal surface that is very evenly planarized can be obtained and contaminants on the crystal surface can be removed to obtain a clean crystal surface at an atomic level. When using the surface-treated crystal, it is possible to fabricate devices having excellent characteristics. For example, as the number of monoatomic step increases, epitaxial growth increases.

Further, the method of controlling the crystal surface morphology according to the present invention can be effectively utilized in the fabrication of nano-sized objects.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of controlling a crystal surface morphology, the method comprising:
heating a crystal having two ends to a predetermined temperature by applying a direct current (DC) voltage to both ends; and
depositing metal atoms at a predetermined deposition rate on the crystal surface, which has been heated to a predetermined temperature, while maintaining the application of the DC voltage so as to form monoatomic steps on the crystal surface.

2. The method of claim 1, wherein the heating temperature of the crystal is in a range of about 700 to about 1000° C.

3. The method of claim 1, wherein the depositing rate of the metal atoms is in a range of about 0.001 to about 1.000 ML/min.

4. The method of claim 1, wherein a depositing time of the metal atoms is in a range of about 1 to about 1000 seconds.

5. The method of claim 4, wherein an average width of monoatomic steps is controlled by controlling the depositing time of the metal atoms.

6. The method of claim 1, wherein the depositing of the metal atoms is performed in a vacuum state of about 10⁻⁹ to about 10⁻¹¹ torr.

7. The method of claim 1, wherein the metal atom is at least one selected from the group consisting of Au, Ti, Ni, Co, Cu, V, Re, Mo and Pt.

8. The method of claim 1, wherein the crystal is a monocrystal.

9. The method of claim 8, wherein the crystal surface on which the metal atoms are deposited is one among (111), (100) and (110) surfaces.

10. The method of claim 1, wherein the crystal is a silicon monocrystal and a magnitude of a DC voltage applied to both ends of the crystal is in a range of about 10 to about 100 V.

11. The method of claim 1, wherein a formation direction of a monoatomic step is controlled by controlling a direction of a DC voltage applied to both ends of the crystal.

12. The method of claim 1, which further comprises, after forming a monoatomic step in the crystal surface, removing the metal atoms deposited on the crystal surface.
